(19) United States
(12) Patent Application Publication
(10) Pub. No.: US 2026/0353827 A1
(43) Pub. Date: Nov. 5, 2026

(54) PIXEL ARRANGEMENT ON TWO SUBSTRATES AND METHOD FOR FABRICATING AN IMAGE SENSOR

(71) Applicant: ams Sensors USA Inc., PLANO, TX (US)

(72) Inventors: Adi XHAKONI, KESSEL LO (BE); Muhammad Maksudur RAHMAN, FREMONT, CA (US); Pascale FRANCIS, UCCLE (BE)

(73) Assignee: ams Sensors USA Inc., PLANO, TX (US)

(21) Appl. No.: 19/109,620

(22) PCT Filed: Sep. 7, 2023
(86) PCT No.: PCT/US2023/032150

§ 371 Date: Mar. 7, 2025

Related U.S. Application Data
(60) Provisional application No. 63/404,637, filed on Sep. 8, 2022.

(51) Int. Cl. H10F 39/00

(52) U.S. Cl. CPC H10F 39/8037; H10F 39/014

(57) ABSTRACT

A pixel arrangement comprises a first semiconductor substrate and a second semiconductor substrate. The first semiconductor substrate comprises a photodiode, a circuit node, a transfer transistor coupled to the photodiode and to the circuit node, an amplifier with an input coupled to the circuit node, and a terminal coupled to an output of the amplifier. The second semiconductor substrate comprises a second capacitor coupled to the terminal, a further amplifier having an input coupled to the second capacitor, a column line and a select transistor coupled to the column line and to an output of the further amplifier. The first or the second semiconductor substrate comprises a first capacitor coupled to the terminal. Furthermore, a method for fabricating a plurality of image sensors is described.

### CROSS-REFERENCE TO RELATED APPLICATION

This patent application is a national stage entry of International Patent Application No. PCT/EP2023/032150, filed on Sep. 7, 2023, and published as WO 2024/054544 A1 on Mar. 14, 2024, and claims the benefit of priority from U.S. Provisional Patent Application No. 63/404,637, filed Sep. 8, 2022, the disclosures of all of which are hereby incorporated by reference in their entireties.

### TECHNICAL FIELD

A pixel arrangement, an image sensor with a pixel arrangement and a method for fabricating a plurality of image sensors are provided.

### BACKGROUND

An image sensor typically comprises a pixel arrangement with an array of photodiodes, several transistors and more than one capacitors. Capacitors with a high capacitance reduce the influence of noise. The capacitors obtain a large area on a semiconductor substrate. However, a small size of a pixel arrangement is advantageous.

Thus, there is a need for a pixel arrangement, an image sensor with a pixel arrangement and a method for fabricating a plurality of image sensors.

### SUMMARY

In an embodiment, a pixel arrangement comprises a first semiconductor substrate and a second semiconductor substrate. The first semiconductor substrate comprises a photodiode, a circuit node, a transfer transistor coupled to the photodiode and to the circuit node, an amplifier with an input coupled to the circuit node, and a terminal coupled to an output of the amplifier. The second semiconductor substrate comprises a second capacitor coupled to the terminal, a further amplifier having an input coupled to the second capacitor, a column line and a select transistor coupled to the column line and to an output of the further amplifier. The first or the second semiconductor substrate comprises a first capacitor coupled to the terminal.

In an embodiment, in a cross section of the pixel arrangement the first capacitor and the second capacitor are placed on top of each other. For example, the second semiconductor substrate comprises the first capacitor and the first and the second capacitor are placed on top of each other.

For example, the first and the second capacitor are placed on top of each other by using different metal schemes. For example, the first capacitor is implemented by two metallization layers of a metallization layer stack and the second capacitor is implemented by two further metallization layers of the metallization layer stack. For example, the first capacitor uses metal 4 and metal 5, and the second capacitor uses metal 6 and metal 7 of same semiconductor substrate.

In an example, the photodiode, the circuit node, the transfer transistor and the amplifier are integrated in the first semiconductor substrate.

In an example, the second capacitor, the further amplifier, the column line and the select transistor are integrated in the second semiconductor substrate.

In an example, the first capacitor is integrated in the first or the second semiconductor substrate.

In an embodiment of the pixel arrangement, the first semiconductor substrate has a first side and a second side. The second semiconductor substrate has a first side and a second side.

In an embodiment of the pixel arrangement, the first side of the first semiconductor substrate is attached to the first side of the second semiconductor substrate. Thus, the transistors, capacitors and the terminal are located at the first side of the first semiconductor substrate and at the first side of the second semiconductor substrate.

In an embodiment of the pixel arrangement, the second side of the first semiconductor substrate is configured for receiving electromagnetic radiation. The photodiode is located at the second side of the first semiconductor substrate.

In an embodiment of the pixel arrangement, the first capacitor comprises one of a group consisting of a metal-isolator-metal capacitor, an interdigitated capacitor and a metal-oxide-semiconductor capacitor.

In an embodiment of the pixel arrangement, the second capacitor comprises one of group consisting of a metal-isolator-metal capacitor, an interdigitated capacitor and a metal-oxide-semiconductor capacitor.

In an embodiment of the pixel arrangement, the metal-isolator-metal capacitor is a high density capacitor. An isolator of the metal-isolator-metal capacitor is a high density material or a high-k material.

In an embodiment of the pixel arrangement, a capacitance of the first capacitor is in a range between 10 fF and 100 fF, alternatively between 20 fF and 80 fF, or alternatively between 30 fF and 50 fF.

In an embodiment of the pixel arrangement, a capacitance of the second capacitor is in a range between 10 fF and 100 fF, alternatively between 20 fF and 80 fF, or alternatively between 30 fF and 50 fF.

In an embodiment of the pixel arrangement, the first semiconductor substrate comprises a first transistor coupled to the output of the amplifier, the terminal and the first capacitor.

In an embodiment of the pixel arrangement, the first capacitor is connected or directly connected to the terminal.

In an alternative embodiment of the pixel arrangement, the first capacitor is coupled via the first transistor to the terminal.

In an embodiment of the pixel arrangement, the first capacitor comprises a first electrode coupled to a node between the first transistor and the terminal. A second electrode of the first capacitor is coupled to a further reference potential terminal.

In an embodiment of the pixel arrangement, the second semiconductor substrate comprises a second transistor coupled to the input of the further amplifier and to the second capacitor.

In a further development of the pixel arrangement, the second transistor is additionally coupled to the terminal.

In an embodiment of the pixel arrangement, the second capacitor is coupled via the second transistor to the terminal and is connected to the input of the further amplifier.

In an alternative embodiment of the pixel arrangement, the second capacitor is connected to the terminal, to the second transistor and to the input of the further amplifier.

In an embodiment of the pixel arrangement, the second capacitor comprises a first electrode coupled or connected to a node between the second transistor and the input of the further amplifier. A second electrode of the second capacitor is coupled or connected to the further reference potential terminal.

In an alternative embodiment of the pixel arrangement, the second capacitor comprises a first electrode coupled or connected to the terminal, and a second electrode coupled or connected to a node between the second transistor and the input of the further amplifier.

In an alternative embodiment of the pixel arrangement, the second capacitor comprises a first electrode coupled or connected to the second transistor, and a second electrode coupled or connected to the further reference potential terminal.

In an embodiment of the pixel arrangement, the first semiconductor substrate comprises a reset transistor coupled to a supply terminal and to the circuit node.

In an embodiment of the pixel arrangement, the first semiconductor substrate comprises a coupling transistor coupled to the circuit node and to the reset transistor.

In an embodiment of the pixel arrangement, the first semiconductor substrate comprises a third capacitor coupled or connected to a node between the reset transistor and the coupling transistor.

In an embodiment of the pixel arrangement, the second semiconductor substrate comprises a reset transistor coupled or connected to a supply terminal and to the terminal.

In an embodiment of the pixel arrangement, the first semiconductor substrate comprises a coupling transistor coupled or connected to the circuit node and to the terminal.

In an embodiment of the pixel arrangement, the first semiconductor substrate comprises a bias transistor. The bias transistor is coupled to the output of the amplifier and to a reference potential terminal.

In an alternative embodiment of the pixel arrangement, the second semiconductor substrate comprises the bias transistor. The bias transistor is coupled to the terminal and to a reference potential terminal.

In an embodiment, an image sensor comprises the first and the second semiconductor substrate. The first semiconductor substrate comprises an array of photodiodes, circuit nodes, transfer transistors, amplifiers, terminals and first capacitors. The second semiconductor substrate comprises column lines and an array of second capacitors, further amplifiers and select transistors. In an embodiment, the image sensor comprises an array of pixels, e.g. an n times m array of pixels. In an example, the image sensor comprises an evaluation circuit and a row driver which are both coupled to the pixel arrangement.

In an example, the number of transistors in one pixel of the pixel arrangement is 8 or 9. The number is at least 8. The number is less than 12 or less than 10.

In an embodiment, a method for fabricating a plurality of image sensors comprises:
Fabricating a first wafer with a first semiconductor substrate,
fabricating a second wafer with a second semiconductor substrate,
realizing a wafer stack of the first wafer and the second wafer by wafer bonding, and
singulating a plurality of image sensors out of the wafer stack.

The first semiconductor substrate comprises a photodiode, a circuit node, a transfer transistor coupled to the photodiode and to the circuit node, an amplifier with an input coupled to the circuit node, and a terminal coupled to an output of the amplifier. The second semiconductor substrate comprises a second capacitor coupled to the terminal, a further amplifier having an input coupled to the second capacitor, a column line and a select transistor coupled to the column line and to an output of the further amplifier. The first or the second semiconductor substrate comprises a first capacitor coupled to the terminal.

Each image sensor of the plurality of image sensors comprises the first semiconductor substrate and the second semiconductor substrate.

The pixel arrangement and the image sensor described above are particularly suitable for the method for fabricating a plurality of image sensors. Features described in connection with the pixel arrangement and the image sensor can therefore be used for the method and vice versa.

In an embodiment, the transfer transistor, the coupling transistor, the reset transistor, the bias transistor, the first transistor, the second transistor and the select transistor are realized as metal-oxide-semiconductor field-effect transistors, abbreviated MOSFETs. For example, each of them is realized as n-channel MOSFET. Alternatively, each of them is realized as p-channel MOSFET.

In an example, the pixel arrangement achieves a small pixel pitch voltage-domain global-shutter pixel. The image sensor is e.g. a global shutter image sensor. The image sensor can be applied e.g. in the consumer, industrial, home and/or automotive market. The image sensor is configured e.g. for augmented reality/virtual reality devices, abbreviated AR/VR devices, mobile three domains authentication, abbreviated mobile 3D authentication, drones, barcode scanner, robotics, machine vision, security, health monitoring, industrial applications etc.

In an example, the image sensor is realized as a CMOS Image sensor, abbreviated CIS or an image sensor module. Advantages are a smaller pixel pitch hence lower cost and size of a camera. The pixel arrangement realizes a reduction of pixel pitch for a global shutter image sensor.

In an example, the pixel is split into two silicon layers or silicon substrates with the storage capacitors on different silicon layers. Splitting the storage capacitors into two silicon layers allows to reduce the pixel pitch when capacitor size limited. In an example, the pixel arrangement allows splitting the pixel capacitors into two semiconductor substrates (e.g. realized as silicon layers), optionally allowing to reduce a pixel pitch from e.g. 2 μm to e.g. 1.4 μm and below.

In an example, pixel circuit splitting the storage capacitors into two silicon layers results in a smaller pixel pitch. The pixel arrangement is fabricated as CMOS image sensor, implements a global shutter or a rolling shutter. The pixel arrangement operates in the voltage domain. The pixel arrangement is sensitive e.g. for near infrared radiation, abbreviated NIR.

With an alternative approach which is having two capacitors in one wafer, it is hardly possible to reduce pixel pitch after dimension. With the described approach, it is possible to shrink the pixel pitch further while maintaining fabrication design rules (which is mandatory for mass production) and maintaining relatively higher capacitor value or values (advantageous for lower read noise) in comparison to the alternative approach which locates each capacitor in the same semiconductor substrate.

In an example, the pixel arrangement allows to reduce voltage domain global shutter pixel pitch while maintaining higher capacitor value which is important for lower read noise. The pixel arrangement comprises e.g.:
Eight or nine transistors voltage domain global shutter pixel.
Two high density Metal on Metal capacitors, abbreviated HDMIM: One in a first wafer which is a sensor wafer and another one in a second wafer.
A backside-illuminated image sensor process, abbreviated BSI process, which enables a good optical performance (particularly NIR responsivity).
An in-pixel stacking process to stack trunk transistors in the second wafer.
The second wafer may contain ASIC circuitry or the ASIC may be in a third wafer.
The pixel arrangement can be operated in a rolling shutter (abbreviated RS) mode, voltage domain global shutter mode or charge domain global shutter mode.

In an example, the circuit node has a capacitive characteristic. The circuit node has a capacitance such as e.g. a diffusion capacitance or a floating diffusion capacitance. Thus, charge provided by the photodiode can applied to the capacitance of the circuit node and to the third capacitor via the transfer transistor and the coupling transistor e.g. in a first storage phase. Thus, the charge provided by the photodiode is detected with low sensitivity by storing this charge not only by the capacitance of the circuit node but also by the third capacitor. This reduces a capacitance voltage at the capacitance of the circuit node. This voltage is amplified and stored e.g. in the first and the second capacitor.

In an example, charge at the capacitance of the circuit node is not provided to the third capacitor via the coupling transistor in a second storage phase. Thus, charge provided by the photodiode can be detected with high sensitivity by storing this charge only by the capacitance of the circuit node and not by the third capacitor. This keeps a voltage swing at the capacitance high. This voltage is amplified and stored e.g. in the first capacitor.

### BRIEF DESCRIPTION OF THE DRAWINGS

The following description of figures of examples or embodiments may further illustrate and explain aspects of the pixel arrangement, the image sensor and the method for fabricating a plurality of image sensors. Arrangements, devices, circuit blocks and layers with the same structure and the same effect, respectively, appear with equivalent reference symbols. In so far as arrangements, devices, circuit blocks and layers correspond to one another in terms of their function in different figures, the description thereof is not repeated for each of the following figures.

FIGS. 1A to 1I show exemplary embodiments of a pixel arrangement;

FIGS. 2A to 2F show exemplary embodiments of an image sensor with a pixel arrangement in a cross section, in a top view and of details; and

FIG. 3 shows an exemplary embodiment of a method for fabricating a plurality of image sensors.

### DETAILED DESCRIPTION

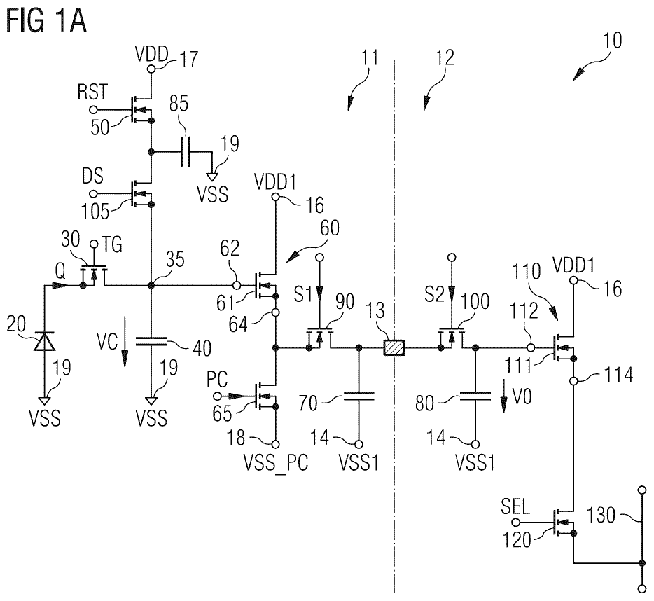

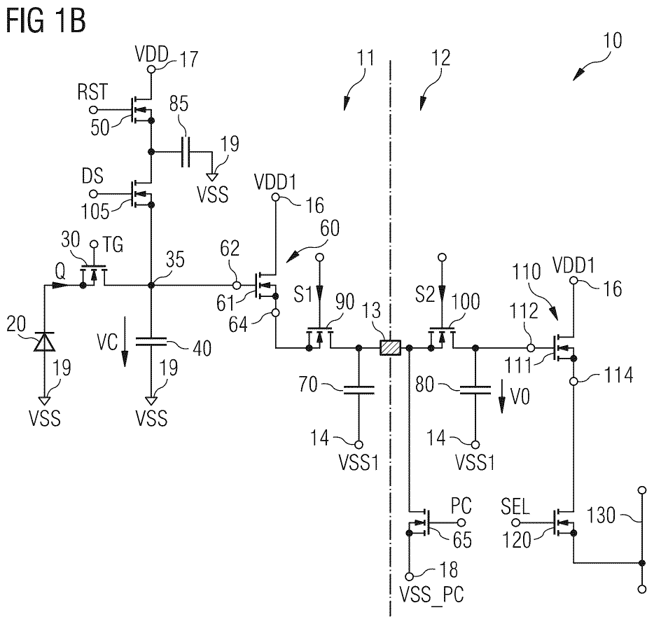

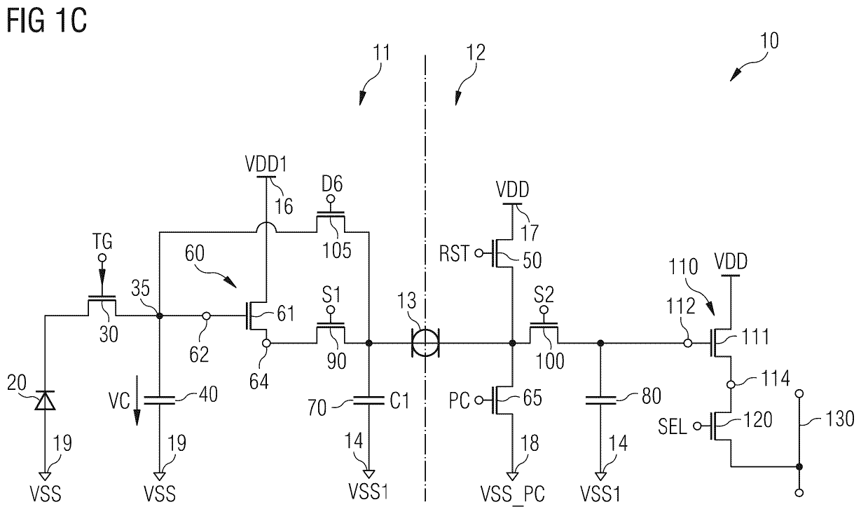

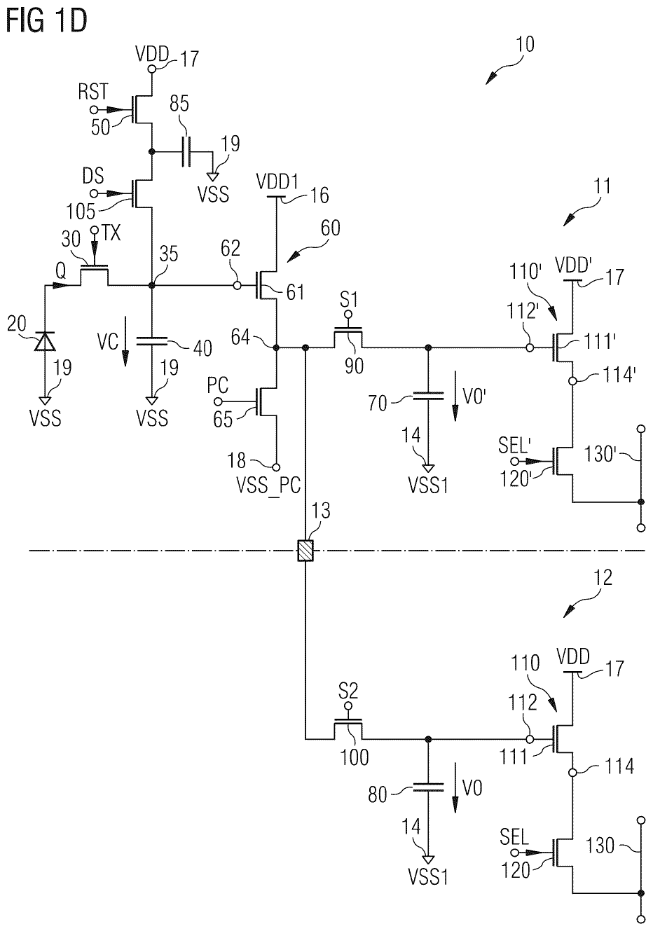

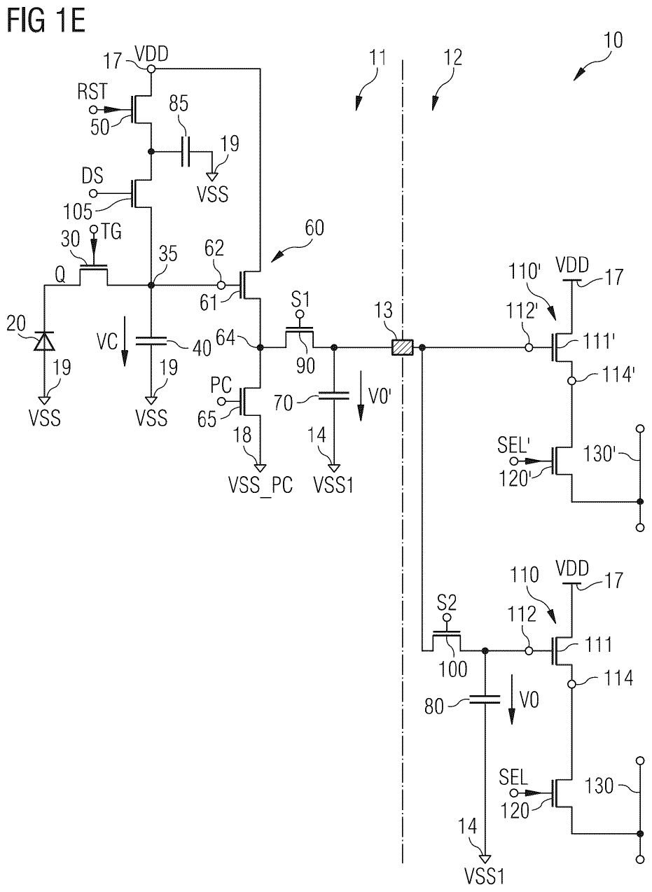

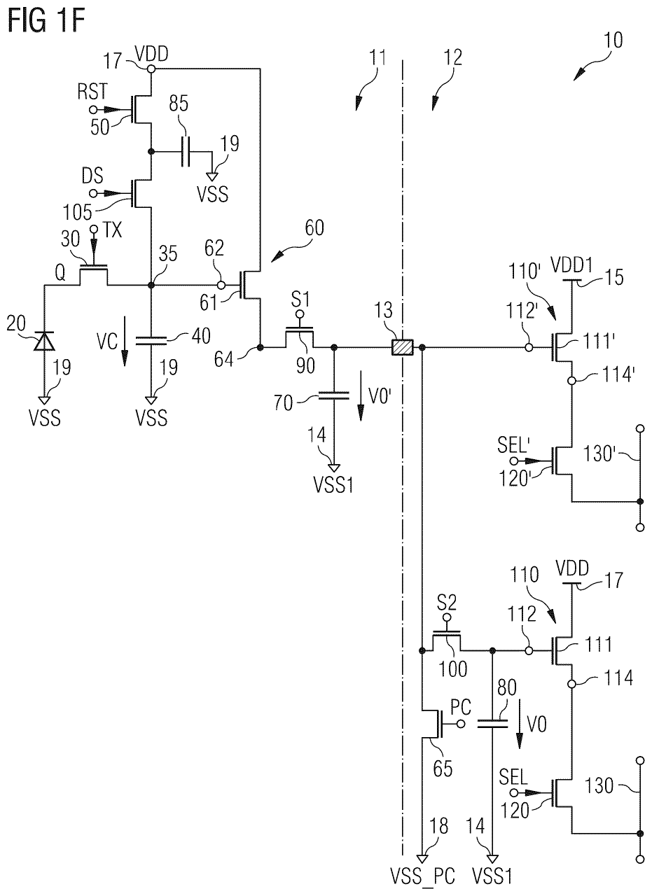

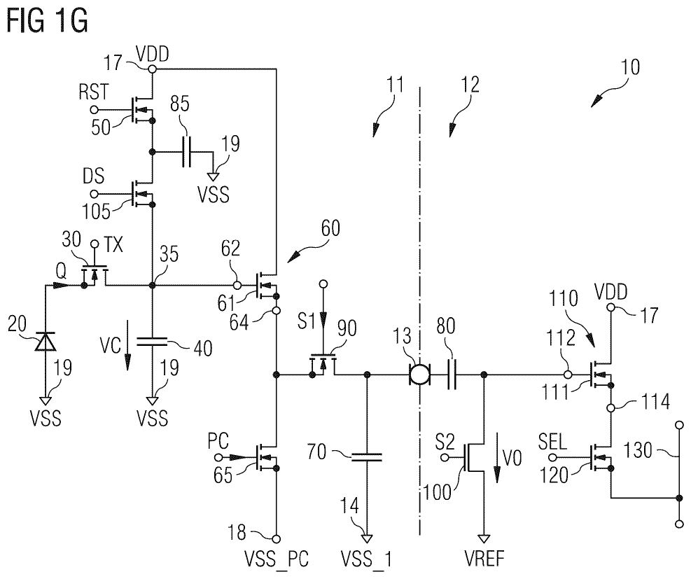

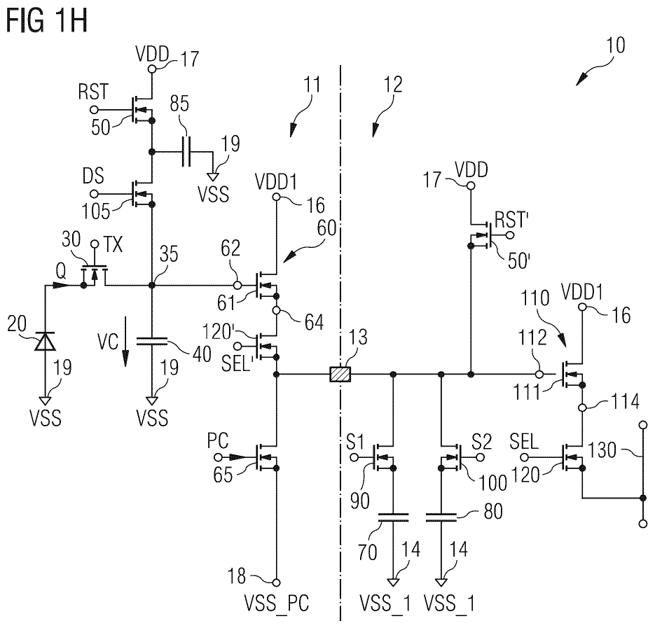

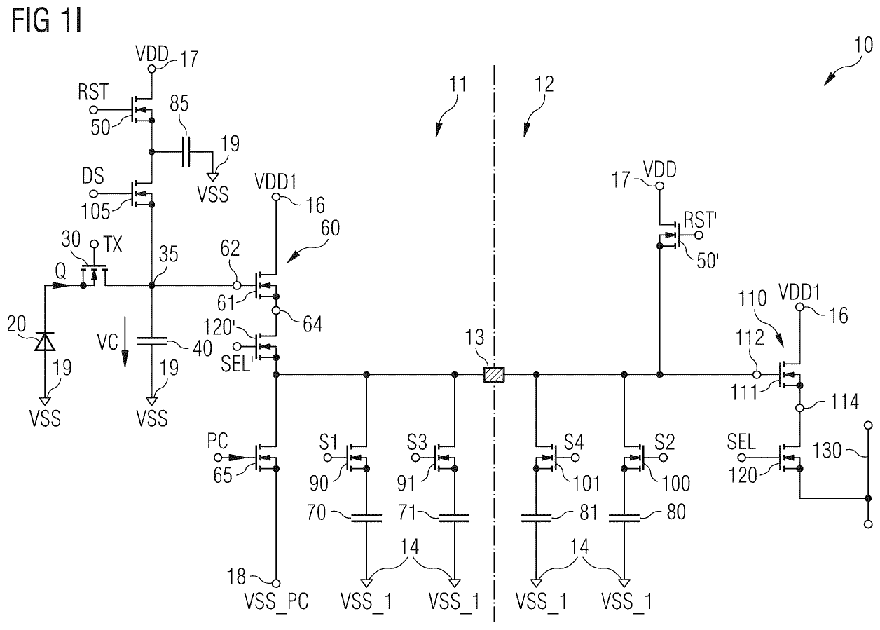

FIG. 1A shows an exemplary embodiment of a pixel arrangement 10. The pixel arrangement 10 comprises a first semiconductor substrate 11 and a second semiconductor substrate 12. The first semiconductor substrate 11 comprises a first part of a circuit of a pixel, and the second semiconductor substrate 11 comprises a second part of the circuit of the pixel. The first and the second semiconductor substrate 11, 12 are made out of e.g. silicon. The first semiconductor substrate 11 comprises a photodiode 20 and a first capacitor 70. Moreover, the first semiconductor substrate 11 comprises a circuit node 35, a transfer transistor 30 coupled to the photodiode 20 and to the circuit node 35 and an amplifier 60 with an input 62 coupled to the circuit node 35. The transfer transistor 30 can also be named transfer gate. A first terminal of a controlled path of the transfer transistor 30 is coupled or connected to the photodiode 20, e.g. to a cathode of the photodiode 20. An anode of the photodiode 20 is connected to a ground terminal 19. A second terminal of the controlled path of the transfer transistor 30 is coupled or connected to the circuit node 35.

Moreover, the first semiconductor substrate 11 comprises a terminal 13. The first capacitor 70 is coupled to an output 64 of the amplifier 60 and to the terminal 13. Moreover, the first semiconductor substrate 11 comprises a first transistor 90 coupled to the output 64 of the amplifier 60, to the terminal 13 and to the first capacitor 70. The first semiconductor substrate 11 comprises a reset transistor 50 coupled to a supply terminal 17 and to the circuit node 35. The first semiconductor substrate 11 comprises a coupling transistor 105 coupled to the circuit node 35 and to the reset transistor 50. The first semiconductor substrate 11 comprises a third capacitor 85 with a first electrode coupled or connected to a node between the reset transistor 50 and the coupling transistor 105. A second electrode of the third capacitor 85 is connected to the ground terminal 19.

The first semiconductor substrate 11 comprises a bias transistor 65 coupled to the output 64 of the amplifier 60 and to a reference potential terminal 18. A first terminal of a controlled path of the bias transistor 65 is coupled or connected to the output 64 of the amplifier 60. A second terminal of the controlled path of the bias transistor 65 is coupled or connected to the reference potential terminal 18.

The first capacitor 70 is connected to the terminal 13. Thus, the first capacitor 70 comprises a first electrode coupled or connected to a node between the first transistor 90 and the terminal 13. A second electrode of the first capacitor 70 is coupled or connected to a further reference potential terminal 14. A first terminal of a controlled path of the first transistor 90 is coupled or connected to the output 64 of the amplifier 60. A second terminal of the controlled path of the first transistor 90 is coupled or connected to the terminal 13 and to the first electrode of the first capacitor 70.

The amplifier 60 comprises an amplifier transistor 61 having a control terminal coupled or connected to the input 62 of the amplifier 60. A first terminal of a controlled path of the amplifier transistor 61 is coupled to a voltage terminal 16. A second terminal of the controlled path of the amplifier transistor 61 is coupled to the output 64 of the amplifier 60. The amplifier 60 is implemented as a source follower.

The second semiconductor substrate 12 comprises a second capacitor 80. The second capacitor 80 is coupled to the terminal 13. The second semiconductor substrate 12 comprises a further amplifier 110 having an input 112 coupled to the second capacitor 80. Additionally, the second semiconductor substrate 12 comprises a column line 130 and a select transistor 120 coupled to the column line 130 and to an output 114 of the further amplifier 110. A first terminal of a controlled path of the select transistor 120 is coupled or connected to the output 114 of the further amplifier 110. A second terminal of the controlled path of the select transistor 120 is coupled or connected to the column line 130.

At least the photodiode 20, the circuit node 35, the transfer transistor 30, the amplifier 60 and the first capacitor 70 are integrated in the first semiconductor substrate 11. At least the second capacitor 80, the further amplifier 110, the column line 130 and the select transistor 120 are integrated in the second semiconductor substrate 12.

For example, a capacitance of the first capacitor 70 and a capacitance of the second capacitor 80 are equal or are different. The capacitance of the first capacitor 70 is e.g. higher than the value of the capacitance 40 of the circuit node 35. The capacitance of the second capacitor 80 is e.g. higher than the value of the capacitance 40 of the circuit node 35. A capacitance of the third capacitor 85 is e.g. higher than the value of the capacitance 40 of the circuit node 35.

A capacitance of the first capacitor 70 is in a range between 10 fF and 100 fF, alternatively between 20 fF and 80 fF, or alternatively between 30 fF and 50 fF. A capacitance of the second capacitor 80 is in a range between 10 fF and 100 fF, alternatively between 20 fF and 80 fF, or alternatively between 30 fF and 50 fF.

The circuit node 35 has a capacitance 40. The capacitance 40 is e.g. a floating diffusion capacitance. The circuit node 35 is e.g. connected to or is equal with a first terminal of the capacitance 40. The capacitance 40 of the circuit node 35 comprises e.g. a capacitance of the control terminal of the amplifier transistor 61, a capacitance of a pn junction of a terminal of the transfer transistor 30 and a capacitance of a pn junction of the first terminal of the coupling transistor 105. Thus, parasitic capacitances of the transistors connected to the circuit node 35 may result in the capacitance 40 of the circuit node 35. The value of the capacitance 40 of the circuit node 35 may be the sum of the values of the parasitic capacitances of the transistors connected to the circuit node 35. Optionally, the pixel arrangement 10 comprises e.g. a capacitor connected to the circuit node 35; this capacitor may contribute to the capacitance 40.

A second terminal of the capacitance 40 is connected to the ground terminal 19. The reference potential terminal 18 is connected to the ground terminal 19 or is not connected to the ground terminal 19. The further reference potential terminal 14 is connected to the ground terminal 19 or is not connected to the ground terminal 19. The further reference potential terminal 14 is connected to the reference potential terminal 18 or is not connected to the reference potential terminal 18.

The second semiconductor substrate 12 comprises a second transistor 100 coupled to the input 112 of the further amplifier 110 and to the second capacitor 80. The second transistor 100 is coupled to the terminal 13. The second capacitor 80 is coupled via the second transistor 100 to the terminal 13. The second capacitor 80 is connected to the input 112 of the further amplifier 110. The first and the second transistor 90, 100 can be named first and second switch.

The second capacitor 80 comprises a first electrode coupled to a node between the second transistor 100 and the input 112 of the further amplifier 110. A second electrode of the second capacitor 80 is coupled to the further reference potential terminal 14. The further amplifier 110 comprises a further amplifier transistor 111 having a control terminal coupled or connected to the input 112 of the further amplifier 110. A first terminal of a controlled path of the further amplifier transistor 111 is coupled to the voltage terminal 16. A second terminal of the controlled path of the further amplifier transistor 111 is coupled or connected to the output 114 of the further amplifier 110. The further amplifier 110 is implemented as a source follower.

The terminal 13 is implemented as pixel level hybrid bond, abbreviated PLHB. The terminal 13 is realized as a metal part or metal plug configured to provide an electrical connection between the first and the second semiconductor substrate 11, 12.

A supply voltage VDD is tapped at the supply terminal 17. A further supply voltage VDD1 is tapped at the voltage terminal 16. A reference potential VSS_PC is tapped at the reference potential terminal 18. A further reference potential VSS1 is tapped at the further reference potential terminal 14. The supply voltage VDD and the further supply voltage VDD1 are positive with respect to the reference potential VSS_PC. The supply voltage VDD and the further supply voltage VDD1 have e.g. different values. A ground potential VSS is tapped at the ground terminal 19. The reference potential VSS_PC, the further reference potential VSS1 and the ground potential VSS have e.g. three different or two different or equal values.

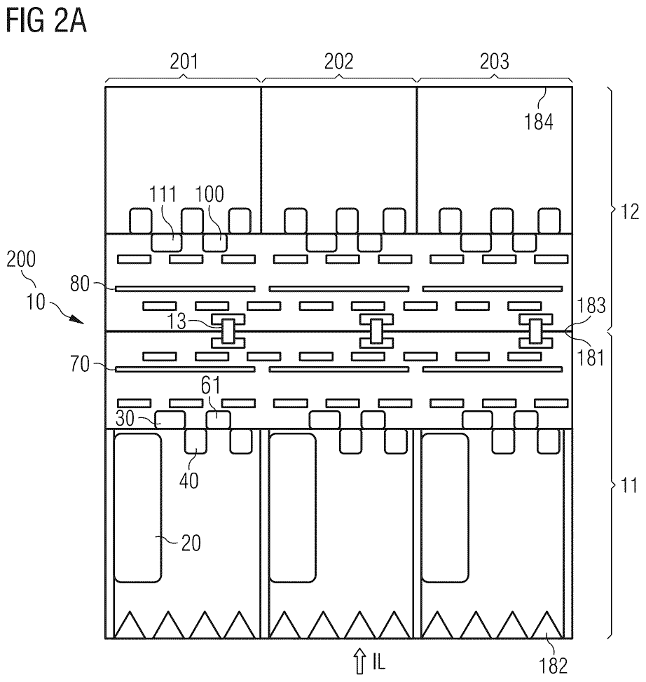

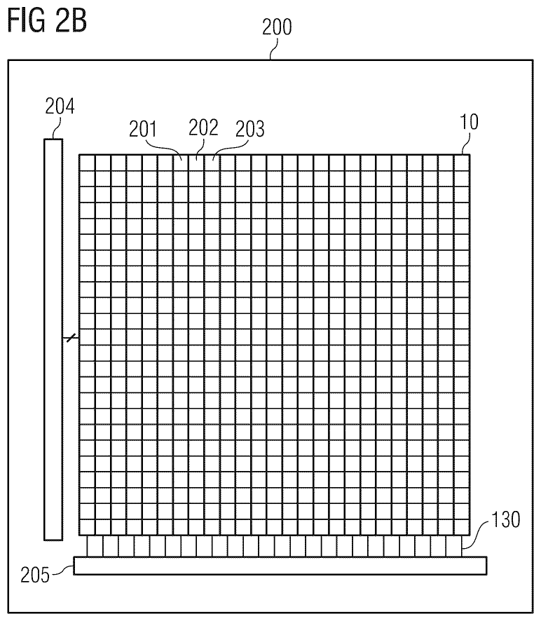

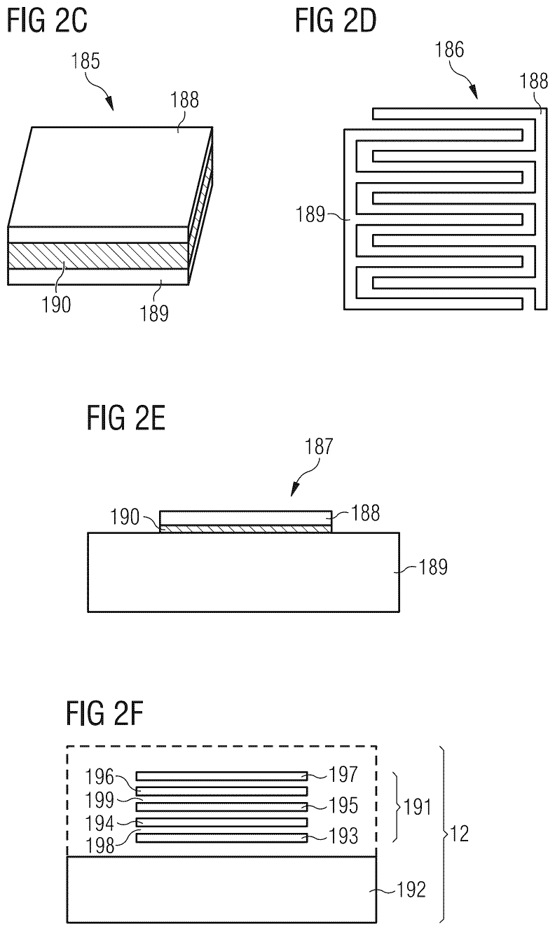

A row driver (shown in FIG. 2) is coupled to the control terminal of the transfer transistor 30, the control terminal of the coupling transistor 105, the control terminal of the reset transistor 50, the control terminal of the bias transistor 65, the control terminal of the first transistor 90, the control terminal of the second transistor 100 and the control terminal of the select transistor 120. The row driver provides a transfer signal TG to the transfer transistor 30, a coupling signal DS to the coupling transistor 105, a reset signal RST to the reset transistor 50, a bias transistor signal PC to the bias transistor 65, a first control signal S1 to the first transistor 90, a second control signal S2 to the second transistor 100 and a select signal SEL to the select transistor 120. In case the reset signal RST sets the bias transistor 65 in a conducting state, the bias transistor 65 delivers a bias current for the amplifier 60.

The pixel arrangement 10 implements a voltage domain global shutter, abbreviated VGS having a pitch that can be minimized by putting the first and the second capacitors 70, 80 in two different wafers and stacked them together to make a pixel. The first and the second capacitors 70, 80 are realized e.g. as high density capacitors.

The implementation of voltage domain global shutter provides at least two capacitors 70, 80 for sampling a reset level and signal level. Thus, the pixel arrangement 10 reduces pixel pitch and still accommodates two capacitors 70, 80. With this approach of two capacitors 70, 80 in two wafers, pixel pitch can be reduced and thus total die size can be reduced. Therefore, the die size will fit for AR/VR applications, where foot print is very important. The first capacitor 70 is in a first wafer which is a sensor wafer. The second capacitor 80 is in a second wafer where some trunk transistor exists. The first and the second capacitor 70, 80 are metal-isolator-metal capacitors, abbreviated MIM capacitors. As the high density MIM capacitors 70, 80 might consume a large area, placing them in two different wafers allows pixel pitch shrinking.

In a storage phase, charge is stored on the first and the second capacitor 70, 80. A capacitance voltage VC tapped at the capacitance 40 of the circuit node 35 is amplified by the amplifier 60 and provided via the first and the second transistor 90, 100 to the first and the second capacitor 70, 80.

Thus, the first capacitor 70 stores a voltage achieved with high conversion gain and the second capacitor 80 stores an output voltage VO achieved with low conversion gain. In other words, a low sensitivity signal is stored on the second capacitor 80 and a high sensitivity signal is stored on the first capacitor 70. This achieves a good low-light performance at a small size of the pixel arrangement 10 by utilizing dual conversion gain and only three capacitors.

Alternatively, the voltage with low conversion gain is stored on the first capacitor 70 and the voltage with high conversion gain is stored on the second capacitor 80.

The pixel arrangement 10 is used e.g. in a voltage domain global shutter pixel, abbreviated VGS pixel, or in a rolling shutter pixel. Two capacitors 70, 80 are utilized with dual conversion gain.

In an alternative embodiment, not shown, the supply terminal 17 is connected to the voltage terminal 16. The supply voltage VDD and the further supply voltage VDD1 are equal.

In an alternative embodiment, not shown, the reference potential terminal 18 is connected to the further reference potential terminal 14. The reference potential VSS_PC and the further reference potential VSS1 are equal.

FIG. 1B shows an exemplary embodiment of a pixel arrangement 10 which is a further development of the embodiment shown in FIG. 1A. The second semiconductor substrate 12 comprises the bias transistor 65. The bias transistor 65 is coupled to the terminal 13 and to the reference potential terminal 18. The first terminal of the controlled path of the bias transistor 65 is coupled or connected to a node between the terminal 13 and the second transistor 100. The second terminal of the controlled path of the bias transistor 65 is coupled or connected to the reference potential terminal 18.

Thus, the number of transistors in the second semiconductor substrate 12 is 4 per pixel and is increased; and the number of transistors in the first semiconductor substrate 11 is 5 per pixel and is decreased in comparison to FIG. 1A.

FIG. 1C shows an exemplary embodiment of a pixel arrangement 10 which is a further development of the embodiments shown in FIGS. 1A and 1B. The second semiconductor substrate 12 comprises the reset transistor 50 coupled to the supply terminal 17 and to the terminal 13. The first semiconductor substrate 11 comprises the coupling transistor 105 coupled to the circuit node 35 and to the terminal 13. A first terminal of a controlled path of the coupling transistor 30 is connected to the circuit node 35. A second terminal of the controlled path of the coupling transistor 30 is connected to the terminal 13. The second semiconductor substrate 12 comprises the bias transistor 65 coupled to the terminal 13 and to the reference potential terminal 18.

Even less transistors are now in the first wafer by using the first capacitor 70 as low gain capacitor and moving the reset transistor 50 to the second wafer, potentially further reducing pixel pitch.

FIG. 1D shows an exemplary embodiment of a pixel arrangement 10 which is a further development of the embodiments shown in FIGS. 1A to 1C. The terminal 13 is coupled to a node between the output 64 of the amplifier 60 and the first transistor 90. Thus, the first capacitor 70 is coupled via the first transistor 90 to the terminal 13. Thus, the first electrode of the first capacitor 70 is coupled or connected to the second terminal of the controlled path of the first transistor 90.

The first semiconductor substrate 11 comprises an additional amplifier 110′ having an input 112′ coupled to the first capacitor 70. The first semiconductor substrate 11 comprises an additional select transistor 120′ which is coupled to an additional column line 130′ and to an output 114′ of the additional amplifier 110′. The first semiconductor substrate 11 comprises the additional column line 130′.

Thus, the pixel arrangement 10 comprises two column lines 130, 130′ for each column. The further amplifier 110 and the additional amplifier 110′ realize two output buffers. The pixel arrangement 10 implements a sample-and-hold circuit on the first wafer and on the second wafer.

FIG. 1E shows an exemplary embodiment of a pixel arrangement 10 which is a further development of the embodiments shown in FIGS. 1A to 1D. The second semiconductor substrate 12 further comprises the additional amplifier 110′ having an input 112′ coupled or connected to the terminal 13. Thus, the input 112′ of the additional amplifier 110′ is coupled via the terminal 13 to the first electrode of the first capacitor 70.

The second semiconductor substrate 12 further comprises the additional select transistor 120′ coupled to the additional column line 130′ and to an output 114′ of the additional amplifier 110′. Optionally, the additional column line 130′ is connected to the column line 130. The pixel arrangement 10 implements both output buffers on the second wafer, one sample-and-hold capacitor 70 on the first wafer and the other sample-and-hold capacitor 80 on the second wafer.

FIG. 1F shows an exemplary embodiment of a pixel arrangement 10 which is a further development of the embodiments shown in FIGS. 1A to 1E. The second semiconductor substrate 12 comprises the bias transistor 65 coupled to the terminal 13 and to the reference potential terminal 18. Thus, the bias transistor 65 couples a node between the terminal 13 and the second transistor 100 to the reference potential terminal 18. The pixel arrangement 10 implements the bias transistor 65 on the second wafer.

FIG. 1G shows an exemplary embodiment of a pixel arrangement 10 which is a further development of the embodiments shown in FIGS. 1A to 1F. The second capacitor 80 is connected to the terminal 13, to the second transistor 100 and to the input 112 of the further amplifier 110. The terminal 13 is coupled via the second capacitor 80 to the second transistor 100 and to the input 112 of the further amplifier 110. The second capacitor 80 comprises a first electrode coupled to the terminal 13 and a second electrode coupled to a node between the second transistor 100 and the input 112 of the further amplifier 110. The pixel arrangement 10 realizes the output buffer 110 and the second capacitor 80 on the second wafer. The second transistor 100 is connected to a reference voltage VREF.

FIG. 1H shows an exemplary embodiment of a pixel arrangement 10 which is a further development of the embodiments shown in FIGS. 1A to 1G. The second semiconductor substrate 12 comprises the first capacitor 70. The second semiconductor substrate 12 comprises e.g. also the first transistor 90. The first capacitor 70 is coupled via the first transistor 90 to the terminal 13. The first capacitor 70 is connected to the first transistor 90 and the first transistor 90 is connected to the terminal 13 and to the input 112 of the further amplifier 110. In other words, the first electrode of the first capacitor 70 is coupled or connected to the first transistor 90. The second electrode of the first capacitor 70 is coupled or connected to the further reference potential terminal 14.

The first semiconductor substrate 11 comprises a further select transistor 120″ which couples the output 64 of the amplifier 60 to the terminal 13. The first semiconductor substrate 11 comprises the bias transistor 65 that couples the terminal 13 to the reference potential terminal 18.

The second capacitor 80 is connected to the second transistor 100 and the second transistor 100 is connected to the terminal 13 and to the input 112 of the further amplifier 110. Thus, the second capacitor 80 is coupled via the second transistor 100 to the terminal 13. In other words, the first electrode of the second capacitor 80 is coupled or connected to the second transistor 100. The second electrode of the second capacitor 80 is coupled or connected to the further reference potential terminal 14. The terminal 13 is directly connected to the input 112 of the further amplifier 110.

In an example, in the embodiments shown in FIGS. 1A to 1C, 1E to 1G or 1I, the second semiconductor substrate 12 comprises the first capacitor 70. The second semiconductor substrate 12 comprises e.g. also the first transistor 90. The first capacitor and the second capacitor 80 are arranged on top of each other; in other words, they are located in a stack configuration.

FIG. 1I shows an exemplary embodiment of a pixel arrangement 10 which is a further development of the embodiments shown in FIGS. 1A to 1H. The first semiconductor substrate 11 comprises the first capacitor 70 and the first transistor 9. The first capacitor 70 is coupled via the first transistor 90 to the terminal 13. Optionally, the first semiconductor substrate 11 comprises a further first capacitor 71 and a further first transistor 91. The further first capacitor 71 is coupled via the further first transistor 91 to the terminal 13. Thus, the first semiconductor substrate 11 comprises a first number of series circuits. Each series circuit comprises a capacitor and a transistor. The capacitor is realized e.g. as the first and the further first capacitor 70, 71. The transistor is realized e.g. as the first and the further first transistor 90, 91. Each of the first number of series circuits couples the terminal 13 to the further reference potential terminal 14. As shown in FIG. 1H, the first number is e.g. 0. As shown in FIG. 1I, the first number is e.g. 2. The first number can be 0 or 1 or 2 or 3 or at least 0 or at least 1 or at least 2. The capacitance values of the capacitors 70, 71 of the first number of series circuits are equal or have at least two different values.

Optionally, the second semiconductor substrate 12 comprises a further second capacitor 81 and a further second transistor 101. The further second capacitor 81 is coupled via the further second transistor 101 to the terminal 13. Thus, the second semiconductor substrate 12 comprises a second number of series circuitries. Each series circuitry comprises a capacitor and a transistor. The capacitor is realized e.g. as the second and the further second capacitor 80, 81. The transistor is realized e.g. as the second and the further second transistor 100, 101. Each of the second number of series circuitries couples the terminal 13 to the further reference potential terminal 14. As shown in FIGS. 1H and 1I, the second number is e.g. 2. The second number can be 1 or 2 or 3 or at least 1 or at least 2. The capacitance values of the capacitors 80, 81 of the second number of series circuitries are equal or have at least two different values. The first number and the second number are equal or are different.

The transistors 30, 50, 61, 65, 90, 100, 105, 111, 120 etc. shown in FIGS. 1A to 1I are field-effect transistors, abbreviated FETs. The transistors are e.g. metal-oxide-semiconductor FETs, abbreviated MOSFETs. The MOSFETs are e.g. n-channel MOSFETs.

FIG. 2A shows an exemplary embodiment of an image sensor 200 with a pixel arrangement 10 in a cross section which is a further development of the embodiments shown in FIGS. 1A to 1I. The first semiconductor substrate 11 has a first side 181 and a second side 182. The second semiconductor substrate 12 has a first side 183 and a second side 184. The first side 181 of the first semiconductor substrate 11 is attached to the first side 183 of the second semiconductor substrate 12. The second side 182 of the first semiconductor substrate 11 is configured for receiving electromagnetic radiation IL.

The first semiconductor substrate 11 of the image sensor 200 comprises an array of photodiodes 20, circuit nodes 35, transfer transistors 30, amplifiers 60, terminals 13 and first capacitors 70 etc. The second semiconductor substrate 12 of the image sensor 200 comprises column lines 130 and an array of second capacitors 80, further amplifiers 110 and select transistors 120 etc. In the example shown in FIG. 2A, the image sensor 200 comprises three pixels 201 to 203. The three pixels 201 to 203 are realized e.g. identically.

The first semiconductor substrate 11 is part of a sensor wafer (named first wafer) comprising the first capacitor 70. The second semiconductor substrate 12 is part of a trunk transistor wafer with the second capacitor 80 and with or without application specific integrated circuit, abbreviated ASIC. The terminal 13 implements a pixel level hybrid bond, abbreviated PLHB

In an alternative embodiment, not shown, the pixel arrangement 10 (and thus the image sensor 200) comprises a third semiconductor substrate. The third semiconductor substrate is realized as ASIC. The third semiconductor substrate comprises e.g. a row driver (shown in FIG. 2B).

FIG. 2B shows an exemplary embodiment of an image sensor 200 with a pixel arrangement 10 in a top view which is a further development of the embodiments shown in FIGS. 1A to 1I and 2A. In FIG. 2B, a view on the first side 183 of the second semiconductor substrate 12 is shown.

The image sensor 200 further comprises a row driver 204 that provides the transfer signal TG, the coupling signal DS, the reset signal RST, the bias transistor signal PC, the first control signal S1, the second control signal S2 and the select signal SEL to the pixel arrangement 10. The row driver 204 provides these signals for each of the rows. The image sensor 200 comprises an evaluation circuit 205 for digitizing the signals at the column lines 130. The pixel arrangement 10 comprises n·m pixels 201 to 203 arranged in an array configuration.

FIG. 2C shows an exemplary embodiment of a capacitor which is a further development of the embodiments of the first and the second capacitor 70, 80 shown above. The capacitor is realized as metal-isolator-metal capacitor 185, abbreviated MIM capacitor. The MIM capacitor 185 is a plate capacitor. The MIM capacitor 185 has a first electrode 188 and a second electrode 189 which are realized e.g. as conductive plates. An insulator layer 190 separates the first electrode 188 from the second electrode 189. The first electrode 188 is e.g. made of a metal, polysilicon or a silicide. The second electrode 189 e.g. made of a metal, polysilicon or a silicide. The insulator layer 190 is made e.g. of silicon dioxide, silicon nitride, aluminum oxide or aluminum nitride.

The metal-isolator-metal capacitor 185 is e.g. a high density capacitor. The insulator layer 190 of the metal-isolator-metal capacitor 185 is a high density material or a high-k material. Aluminum oxide or aluminum nitride are examples for a high density material having a high dielectric constant.

In an example, the first capacitor 70 comprises or is realized as the MIM capacitor 185. In an example, the second capacitor 80 comprises or is realized as the MIM capacitor 185.

FIG. 2D shows an exemplary embodiment of a capacitor which is a further development of the embodiments of the first and the second capacitor 70, 80 shown above. The capacitor is realized as an interdigitated capacitor 186, abbreviated IDC. The capacitor is e.g. a planar capacitor. The IDC 186 capacitor 185 has a first electrode 188 that comprises parallel stripes which are connected to each other. The IDC 186 has a second electrode 189 which comprises parallel stripes which are connected to each other. The stripes of the first electrode 188 have a gap to the stripes of the second electrode 189. The first and the second electrode 188, 189 are arranged between two insulating layers. Thus, the gap is filled by insulating material. Sometimes, the IDC 186 is named metal-oxide-metal capacitor, abbreviated MOM.

The first and the second electrode 188, 189 are e.g. made of a metal, polysilicon or a silicide. The insulator layers are made e.g. of silicon dioxide, silicon nitride, aluminum oxide or aluminum nitride.

In an example, the first capacitor 70 comprises or is realized as the IDC 186. In an example, the second capacitor 80 comprises or is realized as the IDC 186.

FIG. 2E shows an exemplary embodiment of a capacitor which is a further development of the embodiments of the first and the second capacitor 70, 80 shown above. The capacitor is realized as a metal-oxide-semiconductor capacitor 187, abbreviated MOS capacitor. The MOS capacitor 187 has a first electrode 188 which is realized e.g. as conductive plate. The first electrode 188 is e.g. made of a metal, polysilicon or a silicide. The second electrode 189 is realized as a semiconductor portion or semiconductor layer. The insulator layer 190 separates the first electrode 188 from the second electrode 189. The insulator layer 190 is made e.g. of silicon dioxide, silicon nitride, aluminum oxide or aluminum nitride. The MOS capacitor 187 has a high capacitance value which depends on a voltage between the first and the second electrode 188, 189.

In an example, the first capacitor 70 comprises or is realized as the MOS capacitor 187. In an example, the second capacitor 80 comprises or is realized as the MOS capacitor 187.

The first capacitor 70 and the second capacitor 80 can be realized both as MIM capacitor 185, both as IDC 187 or both as MOS capacitor 186. Alternatively, the first capacitor 70 and the second capacitor 80 are realized different.

FIG. 2F shows an exemplary embodiment of a cross section of a second semiconductor substrate 12 which is a further development of the embodiments shown above, especially of FIG. 1H. The second semiconductor substrate 12 comprises a metallization layer stack 191 which includes a plurality of metallization layers 193-197. The metallization layer stack 191 is arranged on top of a semiconductor layer 192 of the second semiconductor substrate 12, such as e.g. a monocrystalline silicon layer. The second capacitor 80 is realized by a first and a second metallization layer 193, 194 of the metallization layer stack 191 and a first insulating layer 198. The first and the second metallization layer 193, 194 are directly adjacent to each other. The first insulating layer 198 separates the first and the second metallization layer 193, 194.

Correspondingly, the first capacitor 70 is realized by a third and a fourth metallization layer 195, 196 of the metallization layer stack 191 and a second insulating layer 199. The third and the fourth metallization layer 195, 196 are directly adjacent to each other. The second insulating layer 199 separates the third and the fourth metallization layer 195, 196.

Alternatively, the first capacitor 70 is realized by the second and the third metallization layer 194, 195 of the metallization layer stack 191 and the second insulating layer 199. The second and the third metallization layer 194, 195 are directly adjacent to each other. The second insulating layer 199 separates the second and the third metallization layer 194, 195. Thus, the first and the second capacitor 70, 80 have a common electrode which, in an example, is connected to the further reference potential terminal 14.

The first and the second capacitor 70, 80 are configured as the metal-isolator-metal capacitor 185, as shown in the example of FIG. 2C. The first and the second insulating layer 198, 199 are realized e.g. as inter-level dielectric layer.

In a cross section of the pixel arrangement 10, the first capacitor 70 and the second capacitor 80 are placed on top of each other. Thus, an area of the second semiconductor substrate 12—e.g. as seen in a top view—is used very efficiently.

Optionally, the metallization layer stack 191 comprises at least a fifth metallization layer 197 which is arranged between the fourth metallization layer 196 and the first side 183 of the second semiconductor substrate 12 and/or between the first metallization layer 193 and the semiconductor layer 192 and/or between the second and the third metallization layer 193, 194.

In an alternative embodiment, one of the first and the second capacitor 70, 80 is realized as metal-isolator-metal capacitor 185 or interdigitated capacitor 186 and the other of the first and the second capacitor 70, 80 is realized as metal-isolator-metal capacitor 185, interdigitated capacitor 186 or metal-oxide-semiconductor capacitor 187. Thus, different realizations of the first and the second capacitor 70, 80 inside the second semiconductor substrate 12 are possible.

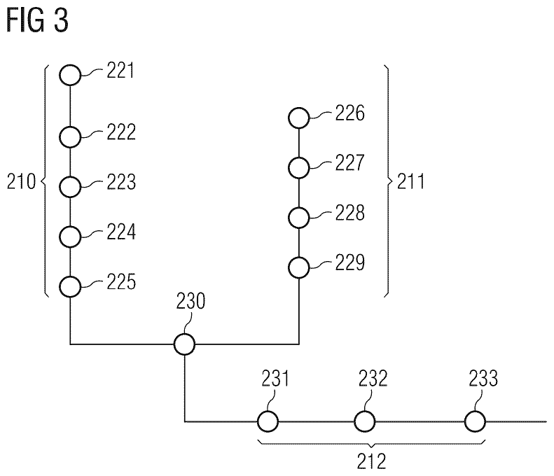

FIG. 3 shows an exemplary embodiment of a method for fabricating a plurality of image sensors 200 which is a further development of the embodiments shown above. The method for fabricating a plurality of image sensors 200 comprises
fabricating a first wafer with the first semiconductor substrate 11 by a first series 210 of steps 221 to 225,
fabricating a second wafer with the second semiconductor substrate 12 by a second series 211 of steps 226 to 229, and
realizing a wafer stack of the first wafer and the second wafer by wafer bonding and singulating a plurality of the image sensors 200 out of the wafer stack by a third series 212 of steps 230 to 233.

The first series 210 of steps 221 to 225 comprises the fabrication of the sensor wafer with the photodiodes 20. The following steps are examples of the steps of the first series 210:
Step 221: performing a shallow trench isolation, abbreviated STI.
Step 222: formation of the photodiodes 20.
Step 223: fabricating the transistors with source, drain and gate.
Step 224: realization of a contact.
Step 225: back end of line process, abbreviated BEOL. The circuit parts such as the transistors, first capacitor 70, part of the terminal 13, photodiode 20 etc. get interconnected by one or more than one metallization layers.

The second series 211 of steps 226 to 229 comprises the fabrication of the transistor wafer with or without the row driver 204 and with or without the evaluation circuit 205. The following steps are examples of the steps of the second series 211:
Step 226: performing a shallow trench isolation, abbreviated STI.
Step 227: fabricating the transistors with source, drain and gate.
Step 228: realization of a contact.
Step 229: back end of line process, abbreviated BEOL. The circuit parts such as the transistors, second capacitor 80, further part of the terminal 13, photodiode 20 etc. are interconnected by one or more than one metallization layers.

The third series 212 of steps 230 to 233 comprises the fabrication of both wafers together. The following steps are examples of the steps of the third series 212:
Step 230: Flip the first wafer (i.e. the sensor wafer) and bond with the second wafer (i.e. the ASIC wafer).
Step 231: Wafer thinning of the first wafer.
Step 232: Etching of a backside deep trench and near infrared (abbreviated NIR) structure formation (optional realization of a contact).
Step 233: formation of pads (e.g. bonding pads).

The pixel arrangement 10 is used e.g. in a voltage domain global shutter pixel, abbreviated VGS pixel. Alternatively, the pixel arrangement 10 is implemented e.g. as a rolling shutter pixel. Two capacitors 70, 80 are utilized with dual conversion gain.

The invention is not limited to the description of the embodiments. Rather, the invention comprises each new feature as well as each combination of features, particularly each combination of features of the claims, even if the feature or the combination of features itself is not explicitly given in the claims or embodiments.

1. A pixel arrangement, comprising:
a first semiconductor substrate and
a second semiconductor substrate,
wherein the first semiconductor substrate comprises:
a photodiode,
a circuit node,
a transfer transistor coupled to the photodiode and to the circuit node,
an amplifier with an input coupled to the circuit node, and
a terminal coupled to an output of the amplifier,
wherein the second semiconductor substrate comprises:
a second capacitor coupled to the terminal,
a further amplifier having an input coupled to the second capacitor,
a column line and
a select transistor coupled to the column line and to an output of the further amplifier, and
wherein the first or the second semiconductor substrate comprises a first capacitor coupled to the terminal.

2. The pixel arrangement of claim 1, wherein in a cross section of the pixel arrangement the first capacitor and the second capacitor are placed on top of each other.

3. The pixel arrangement of claim 1,
wherein the first semiconductor substrate has a first side and a second side,
wherein the second semiconductor substrate has a first side and a second side,
wherein the first side of the first semiconductor substrate is attached to the first side of the second semiconductor substrate, and
wherein the second side of the first semiconductor substrate is configured for receiving electromagnetic radiation.

4. The pixel arrangement of claim 1, wherein the first capacitor comprises one of group consisting of a metal-isolator-metal capacitor, an interdigitated capacitor and a metal-oxide-semiconductor capacitor.

5. The pixel arrangement of claim 1, wherein the second capacitor comprises one of group consisting of a metal-isolator-metal capacitor, an interdigitated capacitor and a metal-oxide-semiconductor capacitor.

6. The pixel arrangement of claim 1, wherein a capacitance of the first capacitor is in a range between 10 fF and 100 fF, and wherein a capacitance of the second capacitor is in a range between 10 fF and 100 fF.

7. (canceled)

8. The pixel arrangement of claim 1, wherein the first semiconductor substrate comprises a first transistor coupled to the output of the amplifier, to the terminal and to the first capacitor.

9. The pixel arrangement of claim 8, wherein the first capacitor is connected to the terminal, or wherein the first capacitor is coupled via the first transistor to the terminal.

10. The pixel arrangement of claim 1, wherein the second semiconductor substrate comprises a second transistor coupled to the input of the further amplifier and to the second capacitor.

11. The pixel arrangement of claim 10,
wherein the second capacitor is coupled via the second transistor to the terminal and is connected to the input of the further amplifier, or
wherein the second capacitor is connected to the terminal, to the second transistor and to the input of the further amplifier, or
wherein the second capacitor is connected to the second transistor and the second transistor is connected to the terminal and to the input of the further amplifier.

12. The pixel arrangement of claim 1, wherein the first semiconductor substrate comprises a reset transistor coupled to a supply terminal and to the circuit node.

13. The pixel arrangement of claim 12, wherein the first semiconductor substrate comprises a coupling transistor coupled to the circuit node and to the reset transistor.

14. The pixel arrangement of claim 13, wherein the first semiconductor substrate comprises a third capacitor coupled to a node between the reset transistor and the coupling transistor.

15. The pixel arrangement of claim 1, wherein the second semiconductor substrate comprises a reset transistor coupled to a supply terminal and to the terminal.

16. The pixel arrangement of claim 1, wherein the first semiconductor substrate comprises a coupling transistor coupled to the circuit node and to the terminal.

17. The pixel arrangement of claim 1, wherein the first semiconductor substrate comprises a bias transistor coupled to the output of the amplifier and to a reference potential terminal.

18. The pixel arrangement of claim 1, wherein the second semiconductor substrate comprises a bias transistor coupled to the terminal and to a reference potential terminal.

19. An image sensor comprising the pixel arrangement of claim 1,
wherein the first semiconductor substrate comprises an array of photodiodes, circuit nodes, transfer transistors, amplifiers, terminals and first capacitors, and
wherein the second semiconductor substrate comprises column lines and an array of second capacitors, further amplifiers and select transistors.

20. A method for fabricating a plurality of image sensors, comprising:
fabricating a first wafer with a first semiconductor substrate,
fabricating a second wafer with a second semiconductor substrate,
realizing a wafer stack of the first wafer and the second wafer by wafer bonding, and
singulating a plurality of the image sensors out of the wafer stack,
wherein the first semiconductor substrate comprises:
a photodiode,
a circuit node,
a transfer transistor coupled to the photodiode and to the circuit node,
an amplifier with an input coupled to the circuit node, and
a terminal coupled to an output of the amplifier, and
wherein the second semiconductor substrate comprises:
a second capacitor coupled to the terminal,
a further amplifier having an input coupled to the second capacitor,
a column line and
a select transistor coupled to the column line and to an output of the further amplifier, and
wherein the first or the second semiconductor substrate comprises a first capacitor coupled to the terminal.

21. A pixel arrangement, comprising:
a first semiconductor substrate and
a second semiconductor substrate,
wherein the first semiconductor substrate comprises:
a photodiode,
a circuit node,
a transfer transistor coupled to the photodiode and to the circuit node,
an amplifier with an input coupled to the circuit node, and
a terminal coupled to an output of the amplifier,
wherein the second semiconductor substrate comprises:
a second capacitor coupled to the terminal,
a further amplifier having an input coupled to the second capacitor,
a column line and
a select transistor coupled to the column line and to an output of the further amplifier, and
wherein the first or the second semiconductor substrate comprises a first capacitor coupled to the terminal, and in a cross section of the pixel arrangement the first capacitor and the second capacitor are placed on top of each other.
